(19) United States
(12) Patent Application Publication
(10) Pub. No.: US 2011/0128807 A1
(43) Pub. Date: Jun. 2, 2011

(54) MEMORY DEVICE AND SENSE CIRCUITRY THEREFOR

(75) Inventors: Ashish Sharma, New Delhi (IN); Lawrence F. Childs, Austin, TX (US); Bikas Maiti, Austin, TX (US); Manmohan Rana, Ghaziabad (IN)

(73) Assignee: FREESCALE SEMICONDUCTOR, INC, Austin, TX (US)

(21) Appl. No.: 12/697,275

(22) Filed: Jan. 31, 2010

(30) Foreign Application Priority Data
Dec. 1, 2009 (IN) 2477/DEL/2009

(51) Int. Cl. G11C 7/00; G11C 7/02; G11C 8/00

(52) U.S. Cl. 365/203; 365/210.1; 365/230.03

(57) ABSTRACT

A memory device includes a memory array, sense circuitry coupled to the memory array, and timing circuitry coupled to the sense circuitry. The timing circuitry generates a sense trigger signal to enable the sense circuitry. A strap region is formed adjacent the memory array. A reference word line is coupled to the timing circuitry. The reference word line formed in the strap region.

### BACKGROUND OF THE INVENTION

The present invention relates generally to memory devices and sense circuitry for memory devices.

Timing circuitry is used in memory devices to track actual memory behavior. The timing circuitry generates a sense trigger signal that is used to enable sense circuitry of a memory device.

Conventional timing circuitry typically seeks to replicate the sense path using dummy word lines, dummy cells, dummy bit lines and the like. However, implementing conventional timing circuitry typically requires a significant amount of circuit area, and even then it may not track the sense path with sufficient accuracy.

As size and speed are both important considerations in memory circuit design, it would be desirable to have a memory device with timing circuitry that uses circuit area more efficiently and tracks actual memory behavior more accurately. It also would be desirable to have faster sense circuitry.

### BRIEF DESCRIPTION OF THE DRAWINGS

The following detailed description of a preferred embodiment of the invention will be better understood when read in conjunction with the appended drawings. The present invention is illustrated by way of example and is not limited by the accompanying figures.

FIG. 1 is a schematic block diagram of a memory device in accordance with an embodiment of the present invention;

FIG. 2 is a schematic circuit diagram illustrating a pull-down circuit in accordance with an embodiment of the present invention;

FIG. 3 is a schematic block diagram illustrating a sense path of the memory device of FIG. 1; and

FIG. 4 is a schematic circuit diagram illustrating sense circuitry for the memory device of FIG. 1.

### DETAILED DESCRIPTION OF THE INVENTION

The detailed description set forth below in connection with the appended drawings is intended as a description of the presently preferred embodiment of the invention, and is not intended to represent the only form in which the present invention may be practiced. It is to be understood that the same or equivalent functions may be accomplished by different embodiments that are intended to be encompassed within the spirit and scope of the invention.

The present invention is directed to a memory device including a memory array, sense circuitry coupled to the memory array, and timing circuitry coupled to the sense circuitry. The timing circuitry generates a sense trigger signal to enable the sense circuitry. A strap region is formed adjacent the memory array. A reference word line is coupled to the timing circuitry. The reference word line is formed in the strap region.

The present invention is also directed to a memory device including a memory array having a plurality of bit lines, sense circuitry coupled to the memory array, and timing circuitry coupled to the sense circuitry. The timing circuitry generates a sense trigger signal to enable the sense circuitry. The sense circuitry includes a plurality of single-ended sense amplifiers and a multiplexer coupled to the single-ended sense amplifiers. Inputs of the single-ended sense amplifiers are connected to respective ones of the plurality of bit lines of the memory array and outputs of the single-ended sense amplifiers are input to the multiplexer.

The present invention is further directed to sense circuitry for a memory device, the sense circuitry including a plurality of single-ended sense amplifiers and a multiplexer coupled to the single-ended sense amplifiers. Inputs of the single-ended sense amplifiers are connected to respective ones of a plurality of bit lines of a memory array, and outputs of the single-ended sense amplifiers are input to the multiplexer.

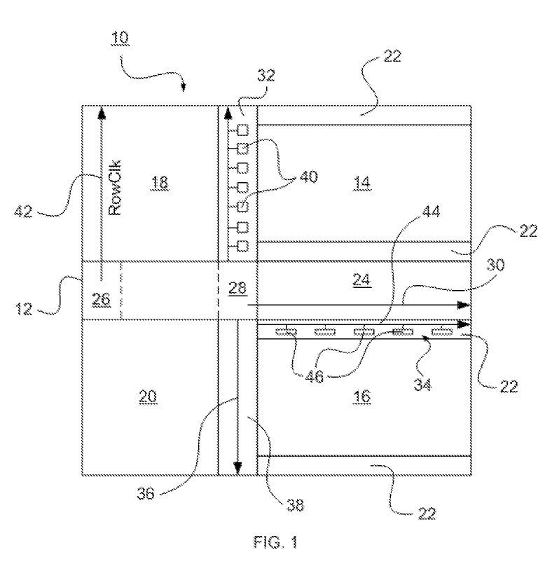

Referring now to FIG. 1, a schematic block diagram of a memory device 10 is shown. The memory device 10 includes control circuitry 12 that is coupled to first and second memory arrays 14 and 16 via first and second row decoder blocks 18 and 20, respectively. Strap regions 22 are formed adjacent the first and second memory arrays 14 and 16. The first and second memory arrays 12 and 14 share and are coupled to sense circuitry 24.

The control circuitry 12 includes a local clock generator 26 and timing circuitry 28 coupled to the sense circuitry 24. The timing circuitry 28 is configured to generate a sense trigger signal 30 that is used to enable the sense circuitry 24. The timing circuitry 28 is coupled to a dummy column 32, a reference word line array 34 and a reference bit line 36 formed in a reference column 38. The timing circuitry 28, the dummy column 32, the reference word line array 34 and the reference bit line 36 are configured to replicate a sense path through the memory device 10.

In the present embodiment, the dummy column 32 and the reference column 38 are formed in a stacked arrangement one on top of the other. More particularly, one of the dummy column 32 and the reference column 38 is formed in an upper memory bank and the other is formed below it in a lower memory bank relative to the upper memory bank. Advantageously, this arrangement of the dummy column 32 and the reference column 38 provides area savings.

The dummy column 32 includes a plurality of dummy loading cells 40. The dummy column 32 is configured to match the capacitance loading on a row clock line 42. The propagation delay experienced by a row clock signal RowClk through the row clock line 42 is thus tracked by the timing circuitry 28 via the dummy column 32. In one embodiment, the number of dummy loading cells 40 and the gate size of each of the dummy loading cells 40 may be the same as on the row clock line 42. Nevertheless, as will be understood by those of ordinary skill in the art, the dummy column 32 may be configured to match the capacitance loading on the row clock line 42 in a different manner in alternative embodiments.

The timing circuitry 28 may also be configured to introduce a delay into the sense path, the delay corresponding to the propagation delay experienced by the row clock signal RowClk as it passes through an actual row decoder (not shown) in the row decoder block 18.

The reference word line array 34 includes a reference word line 44 coupled to the timing circuitry 28 and a plurality of dummy bit cells 46 coupled to the reference word line 44. The reference word line array 34 is configured to match the capacitance loading on an actual word line WL (not shown). As shown in FIG. 1, the reference word line array 34 is formed in one of the strap regions 22 of the memory array 16 and strap cells in the strap region 22 are used as the dummy bit cells 46. Advantageously, the formation of the reference word line array 34 in the strap region 22 of the memory array 16 results in area savings by using existing area more efficiently and circumventing the need to provide additional area for the reference word line array 34.

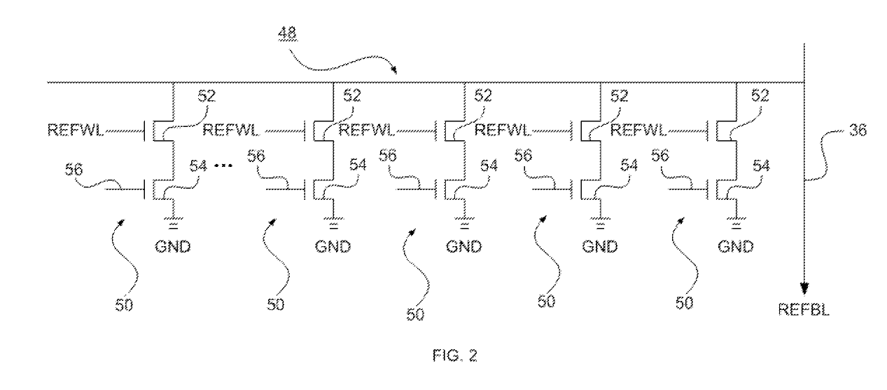

The reference bit line 36 may be discharged by a pull-down circuit in the timing circuitry 28. One embodiment of the pull-down circuit is described in greater detail below with reference to FIG. 2.

Referring now to FIG. 2, a pull-down circuit 48 for discharging the reference bit line 36 is shown. The pull-down circuit 48 includes a plurality of transistor stacks 50.

In the embodiment shown, each of the transistor stacks 50 comprises first and second n-channel transistors 52 and 54. A drain of each of the first n-channel transistors 52 is coupled to the reference bit line 36 and a gate of each of the first n-channel transistors 52 is coupled to the reference word line REFWL. A source of each of the first n-channel transistors 52 is connected to a drain of a corresponding one of the second n-channel transistors 54. A gate of each of the second n-channel transistors 54 is configured to receive a stack selection signal 56, and a source of each of the second n-channel transistors 54 is connected to ground, that is zero (0) potential.

The transistor stacks 50 have different pull-down strengths. The rate of discharge of the reference bit line 36 is adjusted by selecting an appropriate one of the transistor stacks 50 depending on the number of rows in the memory array 16. Generation of the sense trigger signal 30 may be controlled by adjusting the rate of discharge of the reference bit line 36. Advantageously, therefore, the pull-down circuit 48 may be used to adjust the sense margin for different memory configurations.

Referring again to FIG. 1, the control circuitry (other than the timing circuitry 28), the memory arrays 14 and 16, the row decoder blocks 18 and 20, the strap regions 22 and the sense circuitry 24 are well known to those of ordinary skill in the art. Accordingly, detailed description of these components of the memory device 10 is not required for a complete understanding of the present invention.

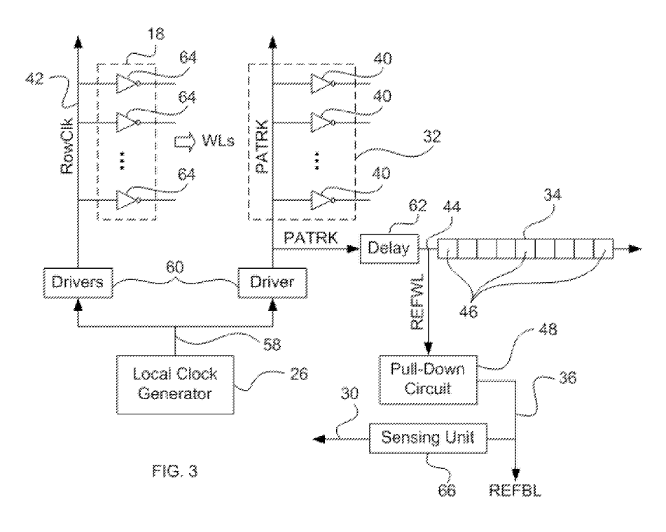

Referring now to FIG. 3, a schematic block diagram illustrating the sense path of the memory device 10 of FIG. 1 is shown. A local clock signal 58 is generated by the local clock generator 26 and is received by respective ones of a plurality of word line drivers 60.

The word line drivers 60 output the row clock signal RowClk on the row clock line 42 and a timing signal PATRK to the dummy column 32. The dummy column 32 is configured to match the capacitance loading on the row clock line 42. This increases the tracking accuracy and consequently the accuracy of the sense margin.

The timing signal PATRK is delayed by a delay element 62 in the timing circuitry 28. The delay introduced into the sense path by the delay element 62 corresponds to the propagation delay experienced by the row clock signal RowClk through an actual row decoder 64 in the row decoder block 18.

The timing signal PATRK is output from the delay element 62 onto the reference word line REFWL 44. Because the reference word line array 34 is configured to match the capacitance loading on an actual word line WL, the capacitance on the reference word line REFWL 44 matches that on an actual word line WL. This increases the tracking accuracy and consequently the accuracy of the sense margin.

The timing signal output from the delay element 62 is received by the pull-down circuit 48 in the timing circuitry 28 and triggers the discharge of the reference bit line 36 coupled to the pull-down circuit 48.

A sensing unit 66 coupled to the reference bit line 36 senses the discharge of the reference bit line 36 and outputs the sense trigger signal 30 in response.

The sense trigger signal 30 is received by and enables the sense circuitry 24.

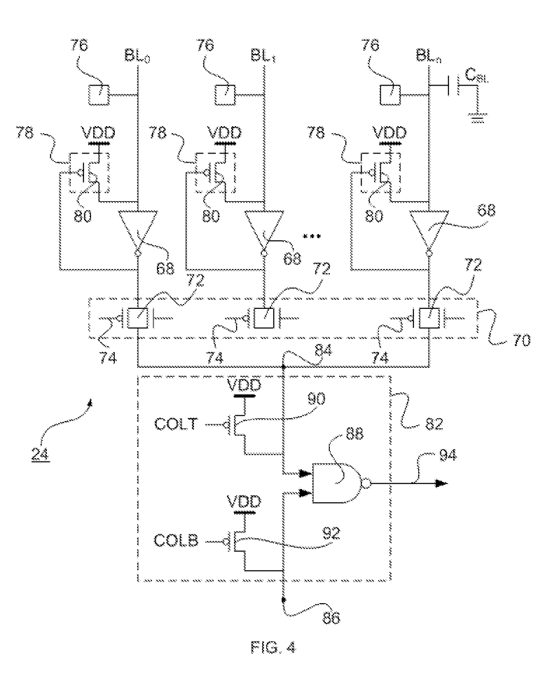

Referring now to FIG. 4, a portion of the sense circuitry 24 of the memory device 10 is shown. The sense circuitry 24 includes a plurality of single-ended sense amplifiers 68 and a multiplexer 70 coupled to the single-ended sense amplifiers 68. Inputs of the single-ended sense amplifiers 68 are connected to respective ones of a plurality of bit lines BL of a memory array and outputs of the single-ended sense amplifiers 68 are input to the multiplexer 70. The multiplexer 70 includes a plurality of transmission gates 72. Each of the transmission gates 72 is coupled to a corresponding single-ended sense amplifier 68 and is configured to receive a column select signal 74. Such multiplexers are well known to those of ordinary skill in the art. Accordingly, detailed description of the multiplexer 70 is not required for a complete understanding of the present invention.

As will be noted by those of ordinary skill in the art, column muxing is performed after sensing in the present embodiment, whereas in prior art schemes, sensing is typically performed after column muxing. Nevertheless, despite the prior art teachings, the inventors have realized that access time can be reduced by connecting the sense amplifiers 66 directly to the bit lines BL, thereby sensing the bit lines BL directly.

The inventors postulate that the reason for this is that by doing so, the capacitance at the inputs of the sense amplifiers 66 comprises substantially only the capacitance C_{BL} on the bit lines BL, and not also the capacitance on the line connecting the column multiplexer to the sense amplifier in prior art schemes. The reduction in the capacitance at the inputs of the sense amplifiers 66 (in some instances, a reduction of more than about 50 percent (%) of the capacitance at the input of a conventional sense amplifier) results in a shorter discharge time and consequently faster sensing compared to prior art schemes.

Another reason postulated by the inventors for the reduction in access time is that by placing the sense amplifiers 66 directly on the bit lines BL, the voltage drop across the transmission gate of the column multiplexer in prior art schemes is avoided. Consequently, improved array efficiency is achieved as word line to data-out delay is largely reduced and in some instances, a reduction of about 25% of the access time is achievable.

In the present embodiment, a plurality of precharge circuits 76 is respectively coupled to ones of the bit lines BL to precharge the bit lines BL directly. Advantageously, this reduces the precharge time.

In the embodiment shown, a plurality of keeper circuits 78 is coupled to respective ones of the bit lines BL. Each of the keeper circuits 78 comprises a p-channel transistor 80 having a source connected to a power supply VDD, a drain connected to a corresponding bit line BL and a gate connected to an output of a corresponding single-ended sense amplifier 68. The keeper circuits 78 are configured to hold a bit line potential of each of the bit lines BL at logic 1 during a read “1” operation to prevent incorrect sensing during the read “1” operation due to high leakage at high temperatures causing the bit line potential to discharge below the read “1” voltage sensing level.

In the present embodiment, a memory bank selection circuit 82 is coupled between output nodes 84 and 86 of the upper and lower memory banks to separate the upper and lower banks of the memory device 10. In the embodiment shown, the selection circuit 82 includes a logic gate 88 having a first input connected to the output node 84 of the upper memory bank and a second input connected to the output node 86 of the lower memory bank, a first p-channel transistor 90 having a source connected to a power supply VDD, a drain connected to the output node 84 of the upper memory bank and a gate configured to receive an upper memory bank selection signal COLT, and a second p-channel transistor 92 having a source connected to a power supply VDD, a drain connected to the output node 86 of the lower memory bank and a gate configured to receive a lower memory bank selection signal COLB. Data stored in the memory device 10 is read out from an output 94 of the logic gate 88.

In the embodiment shown, the logic gate 88 is a NAND gate. Each of the first and second p-channel transistors 90 and 92 is respectively configured to hold the first and second inputs of the logic gate 88 at logic high. For example, if the upper memory bank is to be accessed, the upper memory bank selection signal COLT is held at logic 1 and the lower memory bank selection signal COLB is at logic 0. This ensures correct reading of the upper bank.

Advantageously, the provision of separate sensing nodes 84 and 86 for the upper and lower memory banks reduces the capacitance at the multiplexed nodes 84 and 86 and consequently the sensing time.

The description of the preferred embodiment of the present invention has been presented for purposes of illustration and description, but is not intended to be exhaustive or to limit the invention to the form disclosed. It will be appreciated by those skilled in the art that changes could be made to the embodiment described above without departing from the broad inventive concept thereof. For example, those of ordinary skill in the art will understand that the present invention is not limited to the described memory structure, and may be applied to various types of semiconductor memories including, but not limited to, static random access memory (SRAM), read only memory (ROM), register files, and other types of memory applications. It is understood, therefore, that this invention is not limited to the particular embodiment disclosed, but covers modifications within the spirit and scope of the present invention as defined by the appended claims.

1. A memory device, comprising:
a memory array;
sense circuitry coupled to the memory array;
timing circuitry coupled to the sense circuitry, wherein the timing circuitry generates a sense trigger signal to enable the sense circuitry;
a strap region formed adjacent the memory array; and
a reference word line coupled to the timing circuitry, wherein the reference word line is formed in the strap region.

2. The memory device of claim 1, further comprising a plurality of dummy bit cells coupled to the reference word line, wherein strap cells in the strap region are used as the dummy bit cells.

3. The memory device of claim 1, further comprising a dummy column coupled to the timing circuitry and configured to match a capacitance loading on a row clock line.

4. The memory device of claim 3, wherein the dummy column includes a plurality of dummy loading cells of the same gate size and number as on the row clock line.

5. The memory device of claim 3, further comprising a reference bit line formed in a reference column, wherein the reference column and the dummy column are formed in a stacked arrangement.

6. The memory device of claim 5, further comprising a pull-down circuit configured to discharge the reference bit line.

7. The memory device of claim 6, wherein the pull-down circuit comprises a plurality of transistor stacks having different pull-down strengths.

8. The memory device of claim 1, wherein the timing circuitry is configured to introduce a delay corresponding to a propagation delay experienced by a row clock signal through a row decoder.

9. The memory device of claim 1, wherein the sense circuitry comprises:
a plurality of single-ended sense amplifiers, wherein inputs of the single-ended sense amplifiers are connected to respective ones of a plurality of bit lines of a memory array; and
a multiplexer, wherein outputs of the single-ended sense amplifiers are connected to the multiplexer.

10. The memory device of claim 9, wherein the sense circuitry further comprises a plurality of precharge circuits respectively coupled to ones of the bit lines to precharge the bit lines directly.

11. The memory device of claim 9, wherein the sense circuitry further comprises a plurality of keeper circuits coupled to respective ones of the bit lines.

12. The memory device of claim 1, further comprising a memory bank selection circuit coupled between output nodes of first and second memory banks of the memory device.

13. A memory device, comprising:
a memory array having a plurality of bit lines;
sense circuitry coupled to the memory array; and
timing circuitry coupled to the sense circuitry, wherein the timing circuitry generates a sense trigger signal to enable the sense circuitry,
wherein the sense circuitry comprises:
a plurality of single-ended sense amplifiers, wherein inputs of the single-ended sense amplifiers are connected to respective ones of the plurality of bit lines of the memory array; and
a multiplexer coupled to the single-ended sense amplifiers, wherein outputs of the single-ended sense amplifiers are input to the multiplexer.

14. The memory device of claim 13, further comprising:
a strap region formed adjacent the memory array; and
a reference word line formed in the strap region.

15. The memory device of claim 13, further comprising a dummy column coupled to the timing circuitry, wherein the dummy column matches a capacitance loading on a row clock line.

16. The memory device of claim 15, further comprising a reference bit line formed in a reference column, wherein the reference column and the dummy column are formed in a stacked arrangement.

17. Sense circuitry for a memory device, comprising:
a plurality of single-ended sense amplifiers, wherein inputs of the single-ended sense amplifiers are connected to respective ones of a plurality of bit lines of a memory array; and
a multiplexer coupled to the single-ended sense amplifiers, wherein outputs of the single-ended sense amplifiers are input to the multiplexer.

18. The sense circuitry for a memory device according to claim 17, further comprising a plurality of precharge circuits respectively coupled to ones of the bit lines to precharge the bit lines directly.

19. The sense circuitry of claim 17, further comprising a plurality of keeper circuits coupled to respective ones of the bit lines.

20. The sense circuitry of claim 17, further comprising a memory bank selection circuit coupled between output nodes of first and second memory banks of the memory device.
